(19) United States
(12) Patent Application Publication
(10) Pub. No.: US 2020/0006211 A1
(43) Pub. Date: Jan. 2, 2020

(54) SUBSTRATE ASSEMBLY REGION WITH CERAMIC OR BORON FIBER

(71) Applicant: INTEL CORPORATION, SANTA CLARA, CA (US)

(72) Inventors: Andrew J. BROWN, Phoenix, AZ (US); Lauren A. LINK, Mesa, AZ (US); Sai VADLAMANI, Chandler, AZ (US); Prithwish CHATTERJEE, Tempe, AZ (US); Lisa CHEN, Chandler, AZ (US)

(21) Appl. No.: 16/019,996

(22) Filed: Jun. 27, 2018

(51) Int. Cl. H01L 23/498; H01L 23/14; H01L 23/15; H05K 1/18; H05K 1/03; D06M 11/81; D06B 3/10; D03D 1/00; D03D 15/00; B32B 5/26; B32B 5/02; B32B 7/12

(52) U.S. Cl. CPC H01L 23/49822; B32B 2307/204; H01L 23/15; H05K 1/181; H05K 1/038; D06M 11/81; D06B 3/10; D03D 1/0082; D03D 1/0088; D03D 15/0027; B32B 5/26; B32B 5/024; B32B 7/12; H05K 2201/029; D03D 2700/0166; D10B 2101/20; D10B 2401/16; D10B 2101/08; B32B 2307/202; B32B 2457/08; B32B 2457/14; B32B 2250/20; B32B 2262/12; B32B 2262/103; B32B 2262/105; H01L 23/145

(57) ABSTRACT

Apparatuses, systems and methods associated with substrate assemblies for computer devices are disclosed herein. In embodiments, a core for a substrate assembly includes a first metal region, a second metal region, and a dielectric region located between the first metal region and the second metal region. The dielectric region includes one or more fibers, wherein each of the one or more fibers includes aluminum, boron, silicon, or oxide. Other embodiments may be described and/or claimed.

### TECHNICAL FIELD

The present disclosure relates to the field of electronic circuits. More particularly, the present disclosure relates to substrate assemblies for computer devices.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

In some applications, such as advanced driver assistance systems (ADAS), the reliability standards of computer devices implemented within the applications may be higher than the reliability standards for legacy server and client applications. To achieve the higher reliability standards, components of the computer devices (including substrates) may also have higher reliability standards to be met. A legacy approach to meeting the higher reliability standards for substrates includes increasing thicknesses of one or more layers of the substrates, although this may undesirable for some applications.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a cross sectional view of an example substrate assembly, according to various embodiments.

FIG. 2 illustrates a magnified view of a portion of the example substrate assembly of FIG. 1, according to various embodiments.

FIG. 3 illustrates an example fiber, according to various embodiments.

FIG. 4 illustrates an example procedure for producing a region for a substrate assembly, according to various embodiments.

FIG. 5 illustrates an example CVD process for producing the fiber, according to various embodiments.

FIG. 6 illustrates an example fabric, according to various embodiments.

FIG. 7 illustrates an example impregnation process of the fabric, according to various embodiments.

FIG. 8 illustrates an example core fabrication process, according to various embodiments.

FIG. 9 illustrates a table of properties of an example fabric, according to various embodiments.

FIG. 10 illustrates a portion of an example computer device, according to various embodiments.

FIG. 11 illustrates an example computer device that may employ the apparatuses and/or methods described herein, in accordance with various embodiments.

### DETAILED DESCRIPTION

In embodiments, a core for a substrate assembly includes a first metal region, a second metal region, and a dielectric region located between the first metal region and the second metal region. The dielectric region includes one or more fibers, wherein each of the one or more fibers includes aluminum, boron, silicon, or oxide.

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

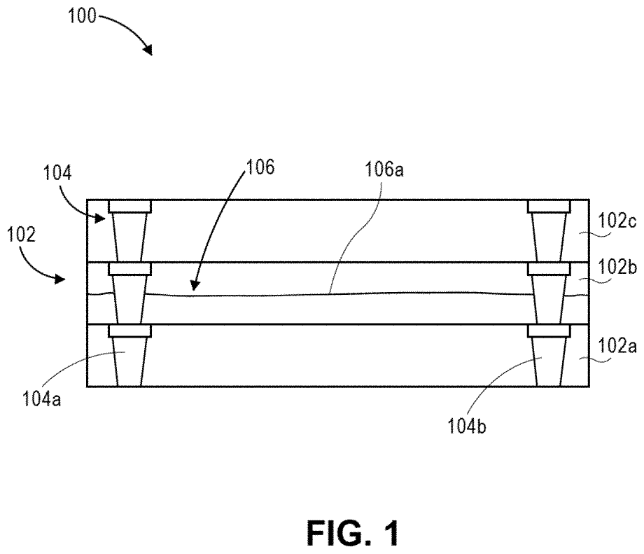

FIG. 1 illustrates a cross sectional view of an example substrate assembly 100, according to various embodiments. The substrate assembly 100 may include one or more regions 102. For example, the substrate assembly 100 includes a first region 102a, a second region 102b, and a third region 102c in the illustrated embodiment. Each of the regions 102 may be a layer of the substrate assembly 100. For example, each of the regions 102 may be a build-up layer or a core (which may also be referred to as a core layer) of the substrate assembly 100.

The substrate assembly 100 may further include one or more conductive elements 104. For example, the substrate assembly 100 includes a first conductive element 104a and a first conductive element 104b. The conductive elements 104 may include one or more traces, vias, pads, conductive layers, or some combination thereof. The conductive elements 104 may be formed of an electrically-conductive material, such as copper, silver, gold, aluminum, zinc, nickel, tin, or some combination thereof.

The substrate assembly 100 may further include one or more sheets of fabric 106. The sheets of fabric 106 may be located within one or more of the regions 102. For example, the second region 102b includes a sheet of fabric 106a in the illustrated embodiment. The second region 102b may be a core of the substrate assembly 100. In other embodiments, the second region 102b may be another layer of the substrate assembly 100, such as a build up layer. The sheets of fabric 106 may extend for the length and the width of the each of the regions 102 in which the sheets of fabric 106 are located. For example, when a sheet of fabric 106 is located within a region 102 that is a layer of the substrate assembly 100, the sheet of fabric 106 may extend for the width and the length of the layer. One or more apertures may be formed in the sheets of fabric 106 through which elements of the substrate assembly 100 may extend, such as the conductive elements 104.

The sheets of fabric 106 may include a plurality of fibers that are weaved together. The fibers may be electrically non-conductive. Accordingly, the sheets of fabric 106 may be electrically non-conductive. Further, the sheets of fabric 106 may include a resin, wherein the plurality of fibers are impregnated with the resin. The resin may include a dielectric material, a ceramic-based material, or some combination thereof. The sheets of fabric 106 may be rigid and may provide stiffness to the regions 102 in which the sheets of fabric 106 are located. In some embodiments, the sheets of fabric 106 may cause the regions 102 in which the sheets of fabric are located to have a tensile modulus between 60 gigapascals (GPa) and 100 GPa. Further characteristics of the fibers and the sheets of fabric 106 are described further throughout this disclosure.

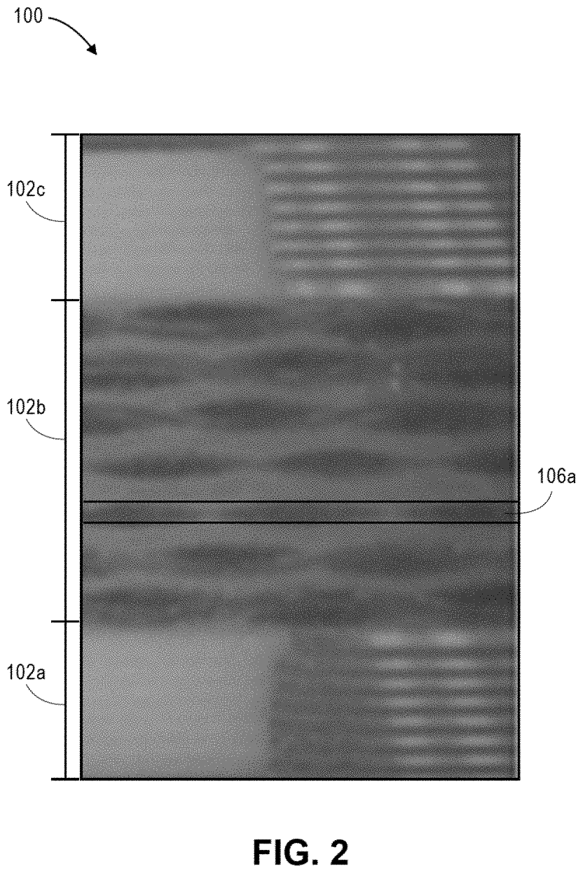

FIG. 2 illustrates a magnified view of a portion of the example substrate assembly 100 of FIG. 1, according to various embodiments. In particular, the magnified view illustrates portions of the first region 102a, the second region 102b, and the third region 102c. Further, the magnified view illustrates the sheet of fabric 106a located within the second region 102b.

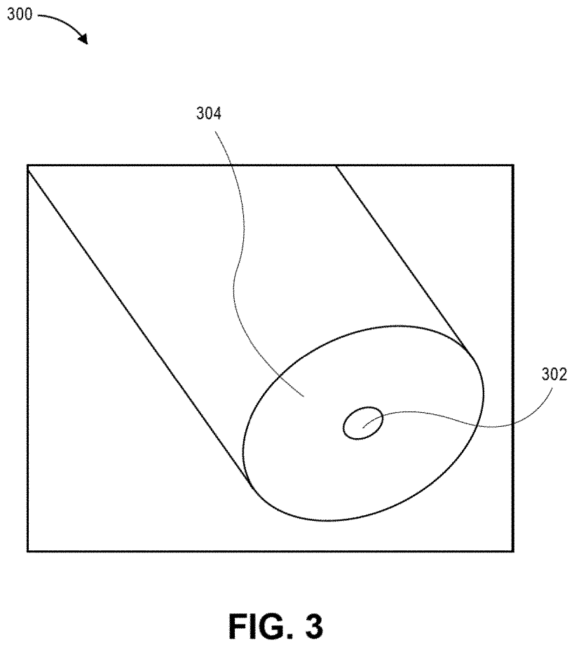

FIG. 3 illustrates an example fiber 300, according to various embodiments. The fiber 300 may implemented within the sheets of fabric 106 (FIG. 1). In particular, each of the sheets of fabric 106 may include a plurality of the fiber 300 weaved together.

The fiber 300 may include a nucleus 302. The nucleus 302 may be located at a center of the fiber 300 and may extend for the length of the fiber 300. The nucleus 302 may comprise an electrically non-conductive material. For example, the nucleus 302 may include aluminum, boron, silicon, oxide, or some combination thereof. In some embodiments, the nucleus 302 may comprise aluminoborosilicate, aluminosilicate, or alumina.

The fiber 300 may further include an outer layer 304. The outer layer 304 may encircle the nucleus 302 and extend for the length of the fiber 300. The outer layer 304 may include boron. The outer layer 304 may be formed on the nucleus 302 via a chemical vapor deposition (CVD) process.

In other embodiments, the fiber 300 may be formed entirely of aluminum, boron, silicon, oxide, or some combination thereof. For example, the fiber 300 may comprise aluminoborosilicate, aluminosilicate, or alumina, in some embodiments. Accordingly, the entire fiber 300 may be formed of a region of aluminoborosilicate, aluminosilicate, or alumina, or the fiber 300 may include the nucleus 302 and the outer layer 304 with each of the nucleus 302 and the outer layer 304 being formed of aluminoborosilicate, aluminosilicate, or alumina.

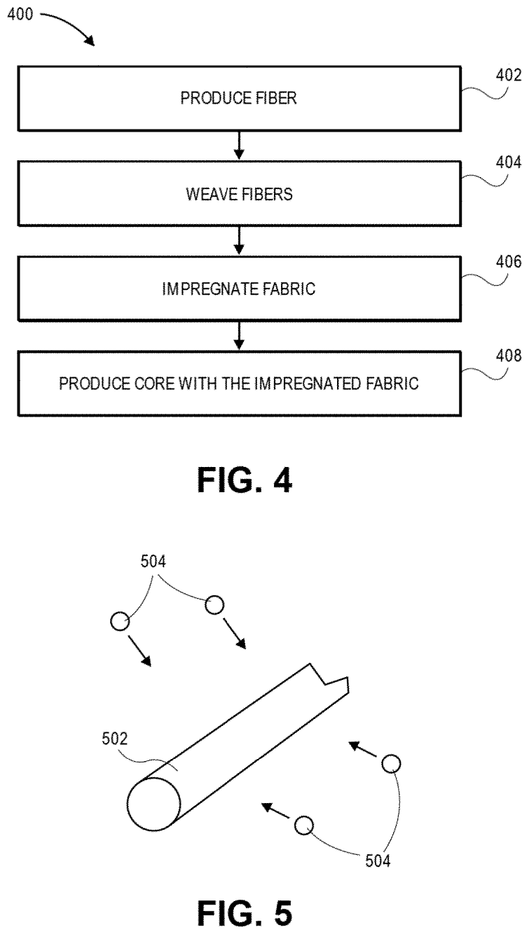

FIG. 4 illustrates an example procedure 400 for producing a region for a substrate assembly, according to various embodiments. In particular, procedure 400 may produce a region having a sheet of fabric, such as the second region 102b (FIG. 1). The illustrated embodiment shows the generation of a core for a substrate assembly, although it is to be understood that the procedure 400, or at least stages 402-406, may be utilized to produce other types of regions for a substrate assembly.

In stage 402, a fiber may be produced. In particular, the fiber produced in stage 402 may include one or more of the feature of the fiber 300 (FIG. 3). Producing the fiber may include performing a deposition process for forming an outer layer (such as the outer layer 304 (FIG. 3)) on a nucleus (such as the nucleus 302 (FIG. 3)). For example, the deposition process may include a CVD process. In other embodiments where the fiber is formed of a region of aluminoborosilicate, aluminosilicate, or alumina, other processes of forming a fiber may be utilized.

FIG. 5 illustrates an example CVD process for producing the fiber, according to various embodiments. In the CVD process, a material to form an outer layer of the fiber may be vaporized for deposition on a nucleus 502 of the fiber. Vaporization of the material may occur in response to the application of heat to the material, a change in atmospheric pressure applied to the material, application of chemicals to the material, or some combination thereof. The material may transition into a plurality of particles 504 (such as molecules, or atoms). The plurality of particles 504 may be directed at, or drawn to, nucleus 502 and form an outer layer (such as the outer layer 304) on the nucleus. In some embodiments, the nucleus 502 may include aluminum, boron, silicon, oxide, or some combination thereof and the particles 504 may be boron particles. Further, the nucleus 502 may be aluminoborosilicate, aluminosilicate, or alumina in some of these embodiments. In other embodiments, both the nucleus 502 and the particles 504 may be aluminoborosilicate, aluminosilicate, or alumina.

In stage 404, a plurality of fibers produced by stage 402 may be weaved together to form fabric. Each of the plurality of fibers may be formed of the same materials, or some of the threads may be formed of a first material and others of the threads may be formed of a second material that is different from the first material. For example, some of the fibers may be formed of aluminoborosilicate, while other of the fibers may be formed of alumina.

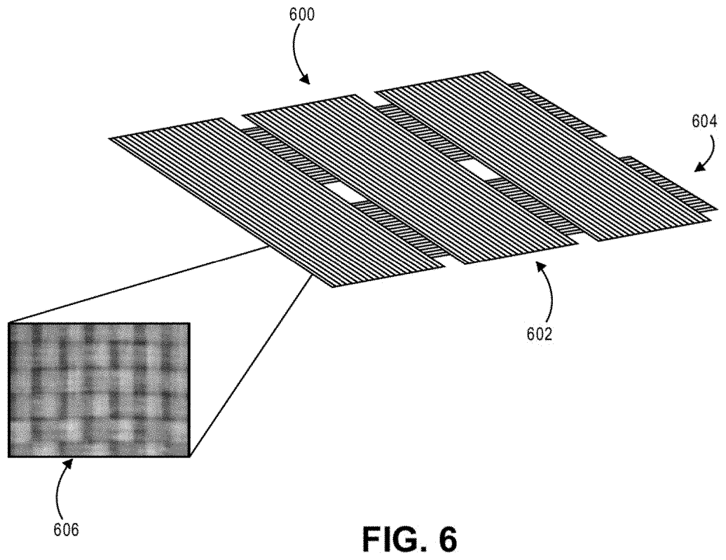

FIG. 6 illustrates an example fabric 600, according to various embodiments. In particular, a plurality of fibers, where each of the fibers may include one or more of the features of the fiber 300 (FIG. 3), produced by stage 402 may be weaved together to produce the fabric 600. In some embodiments, a first portion 602 of the fibers may be arranged in a first direction and a second portion 604 of the fibers may be arranged in a second direction, the second direction being approximately perpendicular (within 10 degrees) to the first direction. The first portion 602 and the second portion 604 of the fibers may be weaved together as shown by enlarged view 606.

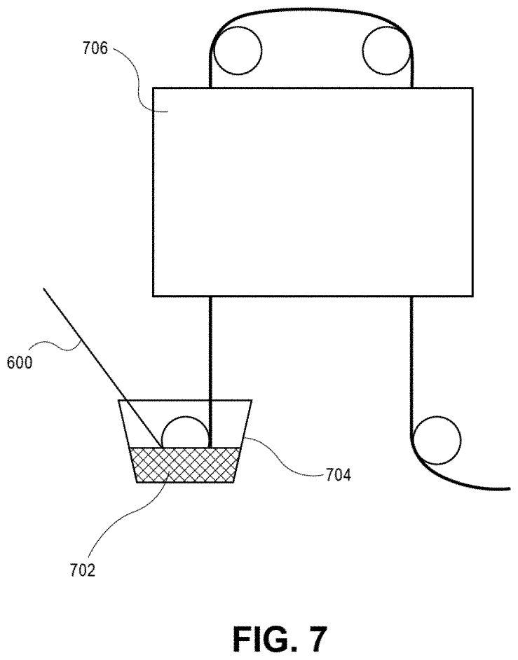

In stage 406, the fabric 600 may be impregnated or coated. In particular, the fabric 600 may be impregnated with a material, such as a dielectric material, a ceramic-based material, or some combination thereof. FIG. 7 illustrates an example impregnation process of the fabric 600, according to various embodiments. The fabric 600 may be coated with a material 702. The material 702 may be a dielectric material, a ceramic-based material, or some combination thereof. For example, the material 702 may be located in a dip tank 704 in liquid form. After being coated with the material 702, a hardening process and/or a drying process may be applied to the fabric 600 that causes the material 702 to harden. For example, heat may be applied to the fabric 600 (as illustrated by heater 706) to cause the material 702 to harden.

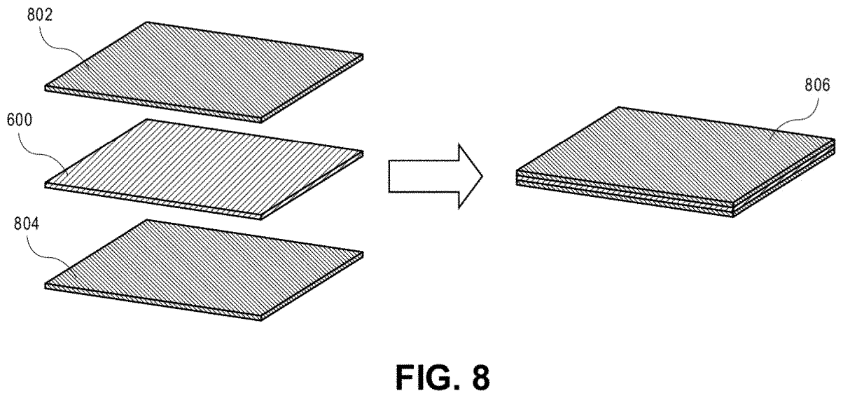

In stage 408, a core for substrate assembly with the impregnated fabric may be produced. FIG. 8 illustrates an example core fabrication process, according to various embodiments. The impregnated fabric 600 may be positioned between a first region 802 and a second region 804. The first region 802 and the second region 804 may include an electrically-conductive material, such as copper, silver, gold, aluminum, zinc, nickel, tin, or some combination thereof. For example, the first region 802 may be a first copper layer and the second region 804 may be a second copper layer. In some embodiments, multiple sheets of the impregnated fabric 600 may be positioned between the first region 802 and the second region 804, where the multiple sheets may be stacked on each other. The first region 802 may be adhered to a first side of the fabric 600 and the second region 804 may be adhered to a second side of the fabric 600, the second side being opposite to the first side. Adhering the first region 802 and the second region 804 to the fabric 600 may include laminating the first region 802 and the second region 804 to the fabric 600, applying epoxy to adhere the first region 802 and the second region 804 to the fabric 600, or some combination thereof. Stage 408 may result in core 806, where the fabric 600 is located between the first region 802 and the second region 804 in the core.

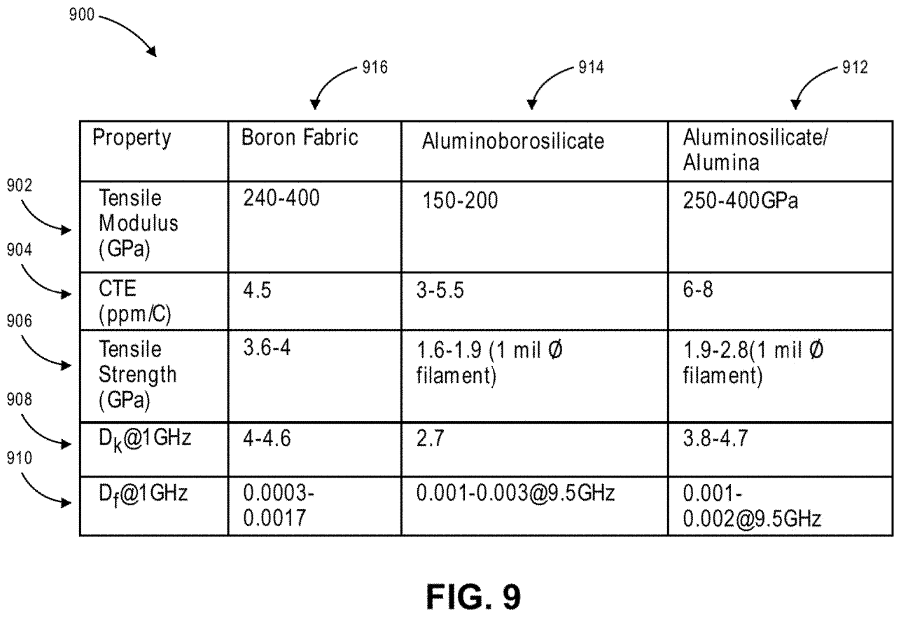

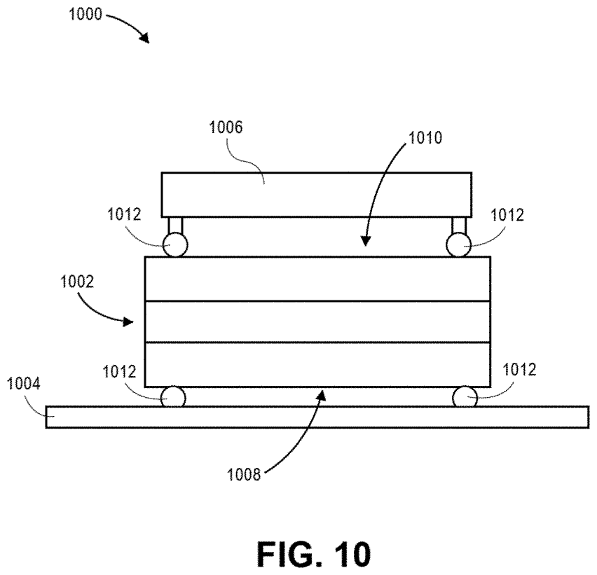

FIG. 9 illustrates a table 900 of properties of example fabrics, according to various embodiments. For example, the properties may be for some embodiments of the fabric 600 (FIG. 6). In particular, the table 900 illustrates the tensile modulus (shown in row 902), the coefficient of thermal expansion (CTE) (shown in row 904), the tensile strength (shown in row 906), the dielectric constant (Dk) at 1 gigahertz (GHz) (shown in row 908), and the dissipation factor (Df) at 1 GHz (shown in row 910) for the fabric and portions thereof.

The table 900 includes properties of aluminosilicate fibers and alumina fibers (shown in column 912) for some embodiments of the fabric. As illustrated, the aluminosilicate fibers and/or alumina fibers may each have a tensile modulus between 250 gigapascals (GPa) and 400 GPa, a coefficient of thermal expansion of between 6 parts per million (ppm) per temperature in degrees Celsius (C) (ppm/C) and 8 ppm/C, a tensile strength between 1.9 GPa and 2.8 GPa, a dielectric constant between 3.8 and 4.7, and a dissipation factor of between 0.001 and 0.002 at 9.5 GHz.

The table 900 further includes properties of aluminoborosilicate fibers (shown in column 914) for some embodiments of the fabric. As illustrated, the aluminoborosilicate fibers may have a tensile modulus between 150 GPa and 200 GPa, a coefficient of thermal expansion of between 3 ppm/C and 5.5 ppm/C, a tensile strength between 1.6 GPa and 1.9 GPa, a dielectric constant of approximately 2.7 (within 0.2), and a dissipation factor of between 0.001 and 0.003 at 9.5 GHz.

The table 900 further includes properties of boron fabric (shown in column 916) for some embodiments of the fabric. As illustrated, the boron fabric may have a tensile modulus between 240 GPa and 400 GPa, a coefficient of thermal expansion of approximately 4.5 ppm/C (within 0.2 ppm/C), a tensile strength between 3.6 GPa and 4 GPa, a dielectric constant of between 4 and 4.6, and a dissipation factor of between 0.0003 and 0.0017 at 1 GHz.

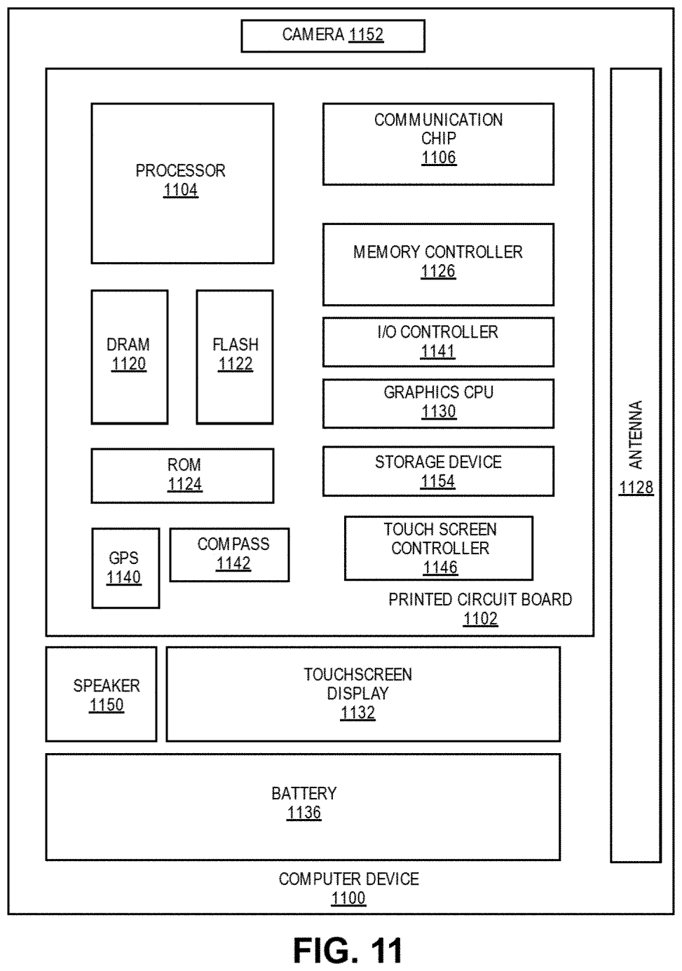

FIG. 10 illustrates a portion 1000 of an example computer device, according to various embodiments. For example, the computer device may include one or more properties of the computer device 1100 (FIG. 11).

The portion 1000 of the computer device may include a substrate assembly 1002. The substrate assembly 1002 may include one or more of the features of the substrate assembly 100 (FIG. 1). In particular, one or more of the regions of the substrate assembly 1002 may include one or more pieces of fabric. Each of the pieces of fabric may include one or more of the features of the piece of fabric 106 (FIG. 1).

The portion 1000 of the computer device may further include a first electrical component 1004 and a second electrical component 1006. The first electrical component 1004 and the second electrical component 1006 may be printed circuit boards (PCBs), semiconductor devices (such as processors, memory devices, and integrated circuits), or some combination thereof. In the illustrated embodiment, the first electrical component 1004 is a PCB and the second electrical component 1006 is a semiconductor device.

The first electrical component 1004 may be coupled to a first side 1008 of the substrate assembly 1002 and the second electrical component 1006 may be coupled to a second side 1010 of the substrate assembly 1002. The first electrical component 1004 and the second electrical component 1006 may each be coupled to the substrate assembly 1002 via one or more interconnect structures (such as solder balls 1012 that are illustrated). The substrate assembly 1002 may electrically couple the first electrical component 1004 and the second electrical component 1006.

FIG. 11 illustrates an example computer device 1100 that may employ the apparatuses and/or methods described herein (e.g., the substrate assembly 100, the fiber 300, the procedure 400, the fabric 600, the core 806, and/or the portion 1000 of the computer device), in accordance with various embodiments. As shown, computer device 1100 may include a number of components, such as one or more processor(s) 1104 (one shown) and at least one communication chip 1106. In various embodiments, the one or more processor(s) 1104 each may include one or more processor cores. In various embodiments, the at least one communication chip 1106 may be physically and electrically coupled to the one or more processor(s) 1104. In further implementations, the communication chip 1106 may be part of the one or more processor(s) 1104. In various embodiments, computer device 1100 may include printed circuit board (PCB) 1102. For these embodiments, the one or more processor(s) 1104 and communication chip 1106 may be disposed thereon. In alternate embodiments, the various components may be coupled without the employment of PCB 1102.

Depending on its applications, computer device 1100 may include other components that may or may not be physically and electrically coupled to the PCB 1102. These other components include, but are not limited to, memory controller 1126, volatile memory (e.g., dynamic random access memory (DRAM) 1120), non-volatile memory such as read only memory (ROM) 1124, flash memory 1122, storage device 1154 (e.g., a hard-disk drive (HDD)), an I/O controller 1141, a digital signal processor (not shown), a crypto processor (not shown), a graphics processor 1130, one or more antenna 1128, a display (not shown), a touch screen display 1132, a touch screen controller 1146, a battery 1136, an audio codec (not shown), a video codec (not shown), a global positioning system (GPS) device 1140, a compass 1142, an accelerometer (not shown), a gyroscope (not shown), a speaker 1150, a camera 1152, and a mass storage device (such as hard disk drive, a solid state drive, compact disk (CD), digital versatile disk (DVD)) (not shown), and so forth.

In some embodiments, the one or more processor(s) 1104, flash memory 1122, and/or storage device 1154 may include associated firmware (not shown) storing programming instructions configured to enable computer device 1100, in response to execution of the programming instructions by one or more processor(s) 1104, to practice all or selected aspects of the methods described herein. In various embodiments, these aspects may additionally or alternatively be implemented using hardware separate from the one or more processor(s) 1104, flash memory 1122, or storage device 1154.

In various embodiments, one or more components of the computer device 1100 may include the substrate assembly 100 (FIG. 1), the fiber 300 (FIG. 1), and/or the fabric 600 (FIG. 6). For example, one or more of the components coupled to the PCB 1102 may couple to the PCB 1102 via a substrate assembly, such as the substrate assembly 100. In particular, the components coupled to the PCB 1102 may include the processor 1104, the communication chips 1106, the DRAM 1120, the flash memory 1122, the ROM 1124, the memory controller 1126, the I/O controller 1141, the graphics CPU 1130, the storage device 1154, the GPS 1140, the compass 1142, and/or the touch screen controller 1146 in some embodiments.

The communication chips 1106 may enable wired and/or wireless communications for the transfer of data to and from the computer device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to IEEE 802.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 1100 may include a plurality of communication chips 1106. For instance, a first communication chip 1106 may be dedicated to shorter range wireless communications such as Wi-Fi and Bluetooth, and a second communication chip 1106 may be dedicated to longer range wireless communications such as GPS, EDGE, GPRS, CDMA, WiMAX, LTE, Ev-DO, and others.

In various implementations, the computer device 1100 may be a laptop, a netbook, a notebook, an ultrabook, a smartphone, a computer tablet, a personal digital assistant (PDA), an ultra-mobile PC, a mobile phone, a desktop computer, a server, a printer, a scanner, a monitor, a set-top box, an entertainment control unit (e.g., a gaming console or automotive entertainment unit), a digital camera, an appliance, a portable music player, or a digital video recorder. In further implementations, the computer device 1100 may be any other electronic device that processes data.

Example 1 may include a core for a substrate assembly, comprising a first metal region, a second metal region, and a dielectric region located between the first metal region and the second metal region, wherein the dielectric region includes one or more fibers, wherein each of the one or more fibers includes aluminum, boron, silicon, or oxide.

Example 2 may include the core of example 1, wherein each of the one or more fibers comprises aluminoborosilicate, aluminosilicate, or alumina.

Example 3 may include the core of example 1, wherein each of the one or more fibers further includes a nucleus formed of an electrically non-conductive material, and an outer layer that encircles the nucleus, the outer layer formed of boron.

Example 4 may include the core of example 3, wherein the electrically non-conductive material comprises aluminoborosilicate, aluminosilicate, or alumina.

Example 5 may include the core of example 1, wherein the one or more fibers comprise a plurality of fibers, wherein the plurality of fibers are woven to produce a fabric.

Example 6 may include the core of example 5, wherein the dielectric region further includes resin, and wherein the fabric is impregnated with the resin.

Example 7 may include the core of example 6, wherein the resin comprises a dielectric material or a ceramic-based material.

Example 8 may include the core of example 5, wherein the fabric has a tensile modulus between 240 gigapascals (GPa) and 400 GPa.

Example 9 may include the core of example 5, wherein the fabric has a tensile strength between 3.6 gigapascals (GPa) and 4 GPa.

Example 10 may include a substrate assembly, comprising one or more regions, wherein a region of the one or more regions includes one or more fibers, and wherein each of the one or more fibers includes aluminum, boron, silicon, or oxide, and one or more conductive elements located within the one or more regions.

Example 11 may include the substrate assembly of example 10, wherein the region comprises a core of the substrate assembly.

Example 12 may include the substrate assembly of example 10, wherein each of the one or more fibers comprises aluminoborosilicate, aluminosilicate, or alumina.

Example 13 may include the substrate assembly of example 10, wherein each of the one or more fibers further includes a nucleus formed of an electrically non-conductive material, and an outer layer that encircles the nucleus, the outer layer formed of boron.

Example 14 may include the substrate assembly of example 13, wherein the electrically non-conductive material comprises aluminum, boron, silicon, or oxide.

Example 15 may include the substrate assembly of example 10, wherein the one or more regions comprise one or more layers of the substrate assembly.

Example 16 may include the substrate assembly of example 10, wherein the one or more fibers comprise a plurality of fibers, and wherein the plurality of fibers are woven to produce a fabric.

Example 17 may include a computer device, comprising a printed circuit board (PCB), a semiconductor device, and a substrate assembly that couples the PCB and the semiconductor device, wherein the substrate assembly includes a plurality of fibers, wherein each of the plurality of fibers includes aluminum, boron, silicon, or oxide.

Example 18 may include the computer device of example 17, wherein the plurality of fibers includes a nucleus formed of an electrically non-conductive material, and an outer layer that encircles the nucleus, the outer layer formed of boron.

Example 19 may include the computer device of example 17, wherein the plurality of fibers are woven to produce a fabric.

Example 20 may include the computer device of example 17, wherein the plurality of fibers are located within a core of the substrate assembly.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

What is claimed is:

1. A core for a substrate assembly, comprising:
a first metal region;
a second metal region; and
a dielectric region located between the first metal region and the second metal region, wherein the dielectric region includes one or more fibers, wherein each of the one or more fibers includes aluminum, boron, silicon, or oxide.

2. The core of claim 1, wherein each of the one or more fibers comprises aluminoborosilicate, aluminosilicate, or alumina.

3. The core of claim 1, wherein each of the one or more fibers further includes:
a nucleus formed of an electrically non-conductive material; and
an outer layer that encircles the nucleus, the outer layer formed of boron.

4. The core of claim 3, wherein the electrically non-conductive material comprises aluminoborosilicate, aluminosilicate, or alumina.

5. The core of claim 1, wherein the one or more fibers comprise a plurality of fibers, wherein the plurality of fibers are woven to produce a fabric.

6. The core of claim 5, wherein the dielectric region further includes resin, and wherein the fabric is impregnated with the resin.

7. The core of claim 6, wherein the resin comprises a dielectric material or a ceramic-based material.

8. The core of claim 5, wherein the fabric has a tensile modulus between 240 gigapascals (GPa) and 400 GPa.

9. The core of claim 5, wherein the fabric has a tensile strength between 3.6 gigapascals (GPa) and 4 GPa.

10. A substrate assembly, comprising:
one or more regions, wherein a region of the one or more regions includes one or more fibers, and wherein each of the one or more fibers includes aluminum, boron, silicon, or oxide; and
one or more conductive elements located within the one or more regions.

11. The substrate assembly of claim 10, wherein the region comprises a core of the substrate assembly.

12. The substrate assembly of claim 10, wherein each of the one or more fibers comprises aluminoborosilicate, aluminosilicate, or alumina.

13. The substrate assembly of claim 10, wherein each of the one or more fibers further includes:
a nucleus formed of an electrically non-conductive material; and
an outer layer that encircles the nucleus, the outer layer formed of boron.

14. The substrate assembly of claim 13, wherein the electrically non-conductive material comprises aluminum, boron, silicon, or oxide.

15. The substrate assembly of claim 10, wherein the one or more regions comprise one or more layers of the substrate assembly.

16. The substrate assembly of claim 10, wherein the one or more fibers comprise a plurality of fibers, and wherein the plurality of fibers are woven to produce a fabric.

17. A computer device, comprising:
a printed circuit board (PCB);
a semiconductor device; and
a substrate assembly that couples the PCB and the semiconductor device, wherein the substrate assembly includes a plurality of fibers, wherein each of the plurality of fibers includes aluminum, boron, silicon, or oxide.

18. The computer device of claim 17, wherein the plurality of fibers includes:
a nucleus formed of an electrically non-conductive material; and
an outer layer that encircles the nucleus, the outer layer formed of boron.

19. The computer device of claim 17, wherein the plurality of fibers are woven to produce a fabric.

20. The computer device of claim 17, wherein the plurality of fibers are located within a core of the substrate assembly.
